(19) United States
(12) Patent Application Publication
(10) Pub. No.: US 2025/0241112 A1
(43) Pub. Date: Jul. 24, 2025

(54) LIGHT-EMITTING ELEMENT, DISPLAY DEVICE, AND METHOD FOR MANUFACTURING LIGHT-EMITTING ELEMENT

(71) Applicant: Sharp Display Technology Corporation, Kameyama City, Mie (JP)

(72) Inventors: Satoru YAMAMOTO, Kameyama City, Mie (JP); Masaya UEDA, Kameyama City, Mie (JP); Takahiro DOE, Kameyama City, Mie (JP)

(21) Appl. No.: 18/699,502

(22) PCT Filed: Dec. 9, 2021
(86) PCT No.: PCT/JP2021/045334

§ 371 Date: Apr. 8, 2024

(51) Int. Cl. H10K 50/115; B82Y 20/00; C09K 11/02; H10K 85/30

(52) U.S. Cl. CPC H10K 50/115; C09K 11/02; H10K 85/30; B82Y 20/00

(57) ABSTRACT

A light-emitting layer includes a quantum dot and a first ligand to be coordinated to the quantum dot, an electron transport layer is in contact with the light-emitting layer and includes a second ligand, and the first ligand and the second ligand have the same functional group, are each a halide ion, or are each a chalcogenide ion, the light-emitting layer includes a first metal element having an ionization tendency equal to or higher than an ionization tendency of lead, the first contact layer includes a second metal element having an ionization tendency equal to or higher than the ionization tendency of lead, the first metal element is selected from a group including alkali metals and alkaline earth metals, and the second metal element is selected from the group including alkali metals and alkaline earth metals.

### TECHNICAL FIELD

The disclosure relates to a light-emitting element, a display device, and a method for manufacturing a light-emitting element.

### BACKGROUND ART

PTL 1 discloses an electroluminescent element including an anode, a hole injection layer, a hole transport layer, a light-emitting layer including a quantum dot to which a ligand is attached, an electron transport layer, and a cathode in this order.

### CITATION LIST

### Patent Literature

PTL 1: Japanese Unexamined Patent Application Publication “JP 2020-77610 A” (published on May 21, 2020)

### SUMMARY

### Technical Problem

However, in the light-emitting element of PTL 1, when a solution containing an electron transport material is applied onto the light-emitting layer, the ligand is easily eluted from the light-emitting layer into the solution.

In a case where the ligand is insufficient in the light-emitting layer, the ligand is removed from a quantum dot and a defect in the surface of the quantum dot is exposed. In the quantum dot in which the defect is exposed, electrons and holes are likely to undergo non-radiative recombination. In addition, the quantum dot in which the defect is exposed is likely to increase in size due to Ostwald growth or aggregation.

These cause a problem such as reduction in luminous efficiency and reliability of the light-emitting element.

### Solution to Problem

A light-emitting element according to an aspect of the disclosure includes: a first electrode; a light-emitting layer including a quantum dot; a first contact layer in contact with the light-emitting layer; and a second electrode, in which the light-emitting layer includes a first ligand to be coordinated to the quantum dot, the first contact layer includes a second ligand, and the first ligand and the second ligand have an identical functional group, each of the first ligand and the second ligand is a halide ion, or each of the first ligand and the second ligand is a chalcogenide ion.

A display device according to an aspect of the disclosure is configured to include the above-described light-emitting element.

A method for manufacturing a light-emitting element according to an aspect of the disclosure is a method including: forming a first electrode; forming a light-emitting layer including a quantum dot; forming a first contact layer in contact with the light-emitting layer; and forming a second electrode, in which in the forming the light-emitting layer, a first liquid including the quantum dot and a first ligand to be coordinated to the quantum dot is applied onto the first electrode, in the forming the first contact layer, a second liquid including a second ligand is applied directly onto the light-emitting layer, and the first ligand and the second ligand have an identical functional group, each of the first ligand and the second ligand is a halide ion, or each of the first ligand and the second ligand is a chalcogenide ion.

### Advantageous Effects of Disclosure

According to an aspect of the disclosure, it is possible to improve luminous efficiency and reliability of a light-emitting element.

### BRIEF DESCRIPTION OF DRAWINGS

FIG. 1 is a schematic plan view illustrating a display device according to an embodiment of the disclosure.

FIG. 2 is a schematic cross-sectional view illustrating a display region illustrated in FIG. 1.

FIG. 3 is a schematic diagram illustrating a schematic configuration of a boundary between a light-emitting layer and an electron transport layer illustrated in FIG. 2 and a vicinity thereof.

FIG. 4 is a schematic flow diagram illustrating an example of a method for manufacturing a display device according to an embodiment of the disclosure.

FIG. 5 is a schematic diagram illustrating an operation of preparing a solution serving as a material of a blue light-emitting layer illustrated in FIG. 2.

FIG. 6 is a schematic diagram illustrating an operation of preparing a solution serving as a material of the electron transport layer illustrated in FIG. 2.

FIG. 7 is a schematic diagram illustrating a schematic configuration of a boundary between the light-emitting layer and a hole transport layer illustrated in FIG. 2 and a vicinity thereof.

FIG. 8 is a schematic cross-sectional view of a display region of a display device according to an embodiment of the disclosure.

FIG. 9 is a schematic diagram illustrating a schematic configuration of a boundary between a light-emitting layer and a hole transport layer illustrated in FIG. 8 and a vicinity thereof.

### DESCRIPTION OF EMBODIMENTS

In the disclosure, a “ligand” refers to an atom, a molecule, or an ion capable of being coordinated to a nanoparticle or a quantum dot, and includes an atom, a molecule, or an ion that is capable of being coordinately bonded to a nanoparticle or a quantum dot but is not actually bonded.

In the disclosure, a “capping agent” refers to a material that is added to a solution as a source of a ligand.

For example, in a case where oleic acid is added to a quantum dot dispersion solution and the oleic acid is coordinated to the quantum dot, the oleic acid is a capping agent and a ligand. Alternatively, for example, in a case where a metal halide compound is added to a quantum dot dispersion solution, and a metal ion and a halide ion are generated from the metal halide compound and the halide ion is coordinated to the quantum dot, the halide compound is a capping agent and the halide ion is a ligand.

### First Embodiment

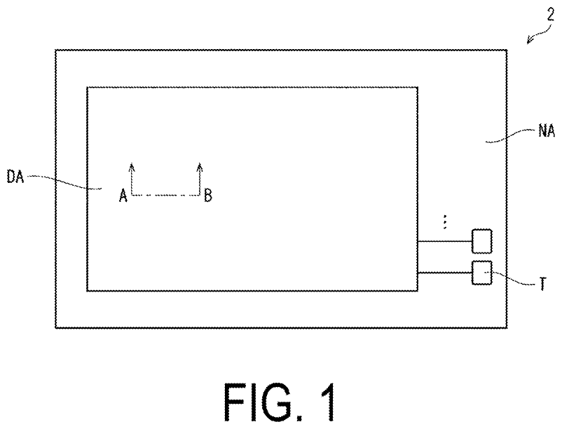

FIG. 1 is a schematic plan view of a display device 2 according to a present embodiment. As illustrated in FIG. 1, the display device 2 according to the present embodiment includes a display region DA in which light emitted from an electroluminescent element of each subpixel is extracted for display, and a frame region NA that surrounds the display region DA. In the frame region NA, terminals T are formed to which signals for driving light-emitting elements of the display device 2 are respectively input.

The display device 2 according to the present embodiment includes a plurality of electroluminescent elements in the display region DA.

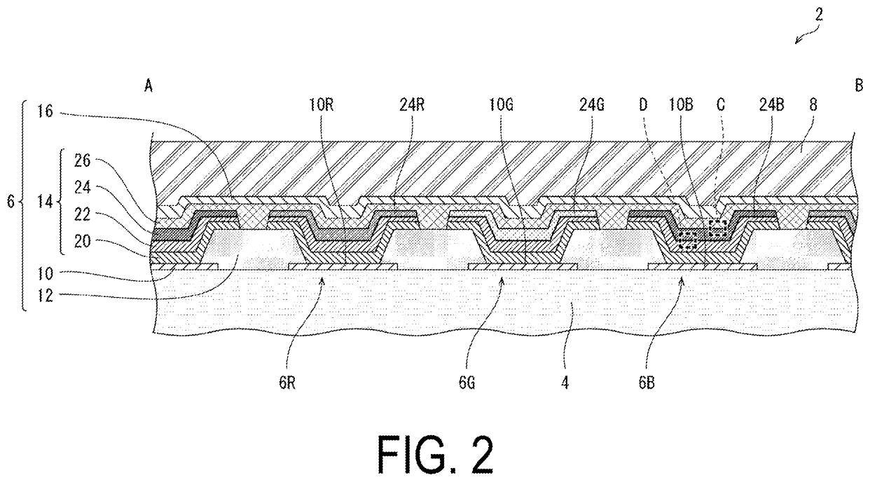

FIG. 2 is a schematic cross-sectional view illustrating the display region DA illustrated in FIG. 1. FIG. 2 corresponds to a cross-sectional view taken along line A-B illustrated in FIG. 1.

FIG. 2 illustrates, of the plurality of electroluminescent elements in the display device 2, a red light-emitting element 6R, a green light-emitting element 6G, and a blue light-emitting element 6B. Unless otherwise specified in the disclosure, “light-emitting element” refers to any one of the red light-emitting element 6R, the green light-emitting element 6G, and the blue light-emitting element 6B.

As illustrated in FIG. 2, the display device 2 includes a substrate 4, a light-emitting element layer 6 above the substrate 4, and a sealing layer 8 covering the light-emitting element layer 6.

In the disclosure, a direction from the light-emitting element layer 6 to the substrate 4 is referred to as a “downward direction”, and a direction from the light-emitting element layer 6 to the sealing layer 8 is referred to as an “upward direction”.

### Substrate

The substrate 4 includes a support substrate. The substrate 4 includes a thin film transistor layer (TFT layer) in which a circuit element such as a thin film transistor (TFT) is provided above the support substrate. The substrate 4 may further include additional components such as a barrier layer. The barrier layer reduces the amount of moisture, oxygen, and the like entering into the light-emitting element layer 6 from the outside of the support substrate.

The support substrate may be a non-flexible substrate made of quartz, glass, or the like or a flexible substrate made of a resin film or a resin sheet. A quartz substrate and a glass substrate are preferable because they have high optical transparency and high gas shielding properties. From the viewpoint of optical transparency and gas shielding properties, the material of the resin film is preferably a methacrylic resin represented by polyethylene methacrylate (PMMA); a polyester resin represented by polyethylene terephthalate (PET), polyethylene naphthalate (PEN), and polybutylene naphthalate (PBN); a polycarbonate resin; or the like.

### Light-Emitting Element Layer

The light-emitting element layer 6 is a layer including light-emitting elements.

The light-emitting element layer 6 includes an anode 10 (first electrode) and a cathode 16 (second electrode) facing each other, an edge cover 12 covering an edge of the anode 10, and an active layer 14 provided between the anode 10 and the cathode 16. The active layer 14 includes a hole injection layer 20, a hole transport layer 22 (second contact layer), a light-emitting layer 24, and an electron transport layer 26 (first contact layer) in this order from the anode 10 side. The active layer 14 is also referred to as an electroluminescence layer (EL layer). This is not a limitation, and the active layer 14 may include additional components such as an electron injection layer.

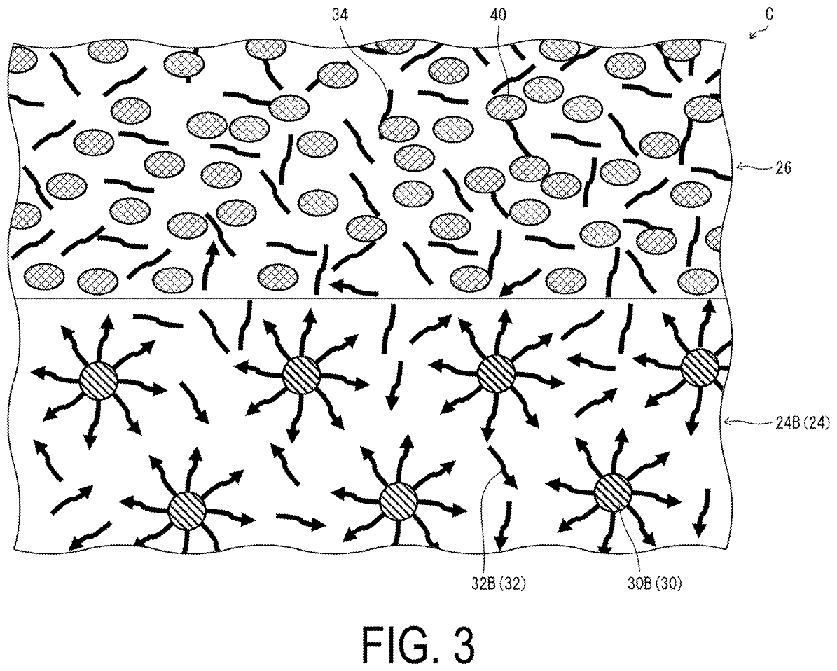

FIG. 3 is a schematic diagram illustrating a schematic configuration of a boundary between the light-emitting layer 24 and the electron transport layer 26 illustrated in FIG. 2 and a vicinity thereof. FIG. 3 corresponds to an enlarged view of a portion indicated by a box C in FIG. 2.

### Electrode

As illustrated in FIG. 2, the anode 10 is formed individually for each light-emitting element. The anode 10 is provided in an island shape for each light-emitting element, that is, for each subpixel and is also referred to as a “pixel electrode”. The anode 10 includes an anode 10R for the red light-emitting element 6R, an anode 10G for the green light-emitting element 6G, and an anode 10B for the blue light-emitting element 6B. On the other hand, the cathode 16 is formed in common for the plurality of light-emitting elements. The cathode 16 is also referred to as a “common electrode”. The cathode 16 faces the pixel electrode, and thus, is also referred to as a “counter electrode”.

Note that the subpixel may be simply referred to as a “pixel”.

The anode 10 and the cathode 16 include an electrically conductive material and at least one is a transparent electrode. In a case where the display device 2 is a single-sided display, the electrode located closer to the display surface from among the anode 10 and the cathode 16 is the transparent electrode, and the electrode located farther from the display surface is a reflective electrode. In a case where the display device 2 is a double-sided display, both the anode 10 and the cathode 16 are transparent electrodes. The transparent electrode can be made of an electrically conductive material with optical transparency. The reflective electrode can be made of conductive material with light reflectivity or can be made of a layered body including a conductive material with optical transparency and a conductive material with light reflectivity.

The conductive material with optical transparency includes indium tin oxide (ITO), indium zinc oxide (IZO), aluminum-doped zinc oxide (AZO), gallium-doped zinc oxide (GZO), tin oxide (SnO₂), fluorine-doped tin oxide (FTO), and the like. Since these materials have a high transmittance with respect to visible light, the luminous efficiency of the light-emitting elements is improved. As the conductive material with light reflectivity, aluminum (Al), silver (Ag), copper (Cu), gold (Au), or the like can be used. Since these materials have a high reflectivity with respect to visible light, the luminous efficiency of the light-emitting elements is improved.

The anode 10 supplies positive holes to the light-emitting layer 24, and the cathode 16 supplies electrons to the light-emitting layer 24. The anode 10 is provided facing the cathode 16.

### Edge Cover

The edge cover 12 may be formed individually for each light-emitting element or may be formed in common for the plurality of light-emitting elements. The edge cover 12 may be of a forward tapered type in which an upper surface is smaller than a bottom surface, or of a reverse tapered type in which the upper surface is larger than the bottom surface. The edge cover 12 may include a single layer or multiple layers.

The edge cover 12 is formed between light-emitting elements adjacent to each other for electrically insulating the light-emitting elements. Thus, the light-emitting element layer 6 is separated into the red light-emitting element 6R, the green light-emitting element 6G, and the blue light-emitting element 6B by the edge cover 12. The edge cover 12 is also referred to as a “partition” or a “bank”. The edge cover 12 has a plurality of openings, and the upper surface of each anode 10 is exposed from each opening.

The edge cover 12 includes an insulating material, for example, a polyimide resin, an acrylic resin, a novolac resin, a fluorene resin, or the like. The edge cover 12 is formed by patterning a photosensitive resin material using, for example, a photolithography technique. The photosensitive resin may be negative or positive.

### Hole Injection Layer and Hole Transport Layer

The hole injection layer 20 is not in contact with the light-emitting layer 24. On the other hand, the hole transport layer 22 is in direct contact with each of the red light-emitting layer 24R, the green light-emitting layer 24G, and the blue light-emitting layer 24B.

Each of the hole injection layer 20 and the hole transport layer 22 may be formed individually for each light-emitting element or may be formed in common for the plurality of light-emitting elements. In a case of being formed individually for each light-emitting element, any one or more of the shape, the thickness, and the composition of the hole injection layer 20 and/or the hole transport layer 22 may be different for each light-emitting element.

The hole injection layer 20 includes a material having hole transport properties and has a function of injecting positive holes from the anode 10 to the hole transport layer 22. The hole transport layer 22 includes a material having hole transport properties and has a function of transporting positive holes from the hole injection layer 20 to the light-emitting layer 24. At least one of the hole injection layer 20 and the hole transport layer 22 preferably has a function of inhibiting the transport of electrons from the light-emitting layer 24 to the anode 10.

As the hole transport material, an inorganic hole transport material or an organic hole transport material may be used. The hole transport material can be appropriately selected from materials generally used in the relevant field.

Examples of the inorganic hole transport material include metal oxides, metal nitrides, metal carbides, metal cyanides, metal thiocyanides, and metal selenium cyanides containing any one or more metal elements of Zn, Cr, Ni, Ti, Nb, Al, Si, Mg, Ta, Hf, Zr, Y, La, Sr, Mo, W, and Re. These materials may be nanoparticles.

Examples of the organic hole transport material include polyethylene dioxythiophene/polystyrene sulphonate (PEDOT: PSS), poly-N-vinyl carbazole (PVK), poly[(9,9-dioctylfluorenyl-2,7-diyl)-co-(4,4′-(N-(4-sec-butylphenyl)diphenylamine)] (TFB), and N,N′-bis(4-butylphenyl)-N,N′-bis(phenyl)-benzidine) (poly-TPD).

### Light-Emitting Layer

The light-emitting layer 24 is formed covering an upper surface of the corresponding anode 10 exposed from an opening of the edge cover 12. The light-emitting layer 24 is a layer that emits light when recombination of positive holes from the anode 10 and electrons from the cathode 16 causes luminescent bodies to excite and then return to a ground state.

The light-emitting layer 24 includes a red light-emitting layer 24R that emits red light, a green light-emitting layer 24G that emits green light, and a blue light-emitting layer 24B that emits blue light. The light-emitting layer 24 may be formed individually for each light-emitting element of the same color or may be formed in common for the plurality of light-emitting elements of the same color.

In the disclosure, “blue light” refers to, for example, light having a light emission central wavelength in a wavelength band from 400 nm to 500 nm. Also, “green light” refers to, for example, light having a light emission central wavelength in a wavelength band from greater than 500 nm to 600 nm. Also, “red light” refers to, for example, light having a light emission central wavelength in a wavelength band of greater than 600 nm to 780 nm.

Note that the light-emitting layer 24 according to the disclosure is not limited thereto. For example, the light-emitting layer 24 may include a layer that emits light of a color other than red, green, and blue. Also, for example, the light-emitting layer 24 may emit light of two colors or less or may emit light of four colors or more.

As illustrated in FIG. 3, the blue light-emitting layer 24B includes a blue quantum dot 30B that emits blue light as a luminescent body, and further includes a first ligand 30B to be coordinated to the blue quantum dot 32B.

Although not illustrated, similarly, the green light-emitting layer 24G includes a green quantum dot that emits green light as a luminescent body, and further includes a green first ligand to be coordinated to the green quantum dot. In addition, the red light-emitting layer 24R includes a red quantum dot that emits red light as a luminescent body, and further includes a red first ligand to be coordinated to the red quantum dot.

The red quantum dot, the green quantum dot, and the blue quantum dot 30B may have the same or different compositions. The first ligand of the red light-emitting layer 24R, the first ligand of the green light-emitting layer 24G, and the first ligand 32B of the blue light-emitting layer 24B may be the same as or different from each other.

In the disclosure, unless otherwise specified, a “quantum dot 30” refers to any one of the red quantum dot, the green quantum dot, and the blue quantum dot 30B. A “first ligand 32” refers to any one of the first ligand of the red light-emitting layer 24R, the first ligand of the green light-emitting layer 24G, and the first ligand 32B of the blue light-emitting layer 24B. The first ligand 32 will be described in detail below.

For example, the quantum dot 30 is a semiconductor fine particle which has a particle size of 100 nm or less and can include a group II-VI semiconductor compound such as MgS, MgSe, MgTe, CaS, CaSe, CaTe, SrS, SrSe, SrTe, BaS, BaSe, BaTe, ZnS, ZnSe, ZnTe, CdS, CdSe, CdTe, CdZnSe, HgS, HgSe, and HgTe, and/or a crystal of a group III-V semiconductor compound such as GaAs, GaP, InN, InAs, InP, and InSb, and/or a crystal of a group IV semiconductor compound such as Si, Ge, Sn, and Pb. Furthermore, the quantum dot may have, for example, a core/shell structure in which the semiconductor crystal described above is a core and a shell material having a high band gap is coated over the core.

### Electron Transport Layer

As illustrated in FIG. 2, the electron transport layer 26 according to the present embodiment is in direct contact with each of the red light-emitting layer 24R, the green light-emitting layer 24G, and the blue light-emitting layer 24B.

The electron transport layer 26 may be formed individually for each light-emitting element or may be formed in common for the plurality of light-emitting elements. In a case of being formed individually for each light-emitting element, any one or more of the shape, the thickness, and the composition of the electron transport layer 26 may be different for each light-emitting element.

As illustrated in FIG. 3, the electron transport layer 26 includes an electron transport material 40 having an electron transport property, and further includes a second ligand 34 capable of being coordinated to the quantum dot 30. In a case where the second ligand 34 has a sufficient electron transport property for the electron transport layer 26, the second ligand 34 may also serve as the electron transport material 40. The second ligand 34 will be described in detail below.

The electron transport layer 26 has a function of transporting electrons from the cathode 16 to the light-emitting layer 24. The electron transport layer 26 preferably has a function of inhibiting the transport of positive holes from the light-emitting layer 24 to the cathode 16. As the electron transport material, an inorganic electron transport material or an organic electron transport material may be used. The electron transport material can be appropriately selected from materials generally used in the relevant field.

Examples of the inorganic electron transport material include metal oxides including any one or more metal elements of Zn, Ti, Mg, Zr, Sn, and Nb. These materials may be nanoparticles.

Examples of the organic electron transport material include compounds and complexes including one or more nitrogen-containing heterocycles such as an oxadiazole ring, a triazole ring, a triazine ring, a quinoline ring, a phenanthroline ring, a pyrimidine ring, a pyridine ring, an imidazole ring, and a carbazole ring. Specific examples include 1,10-phenanthroline derivatives such as bathocuproine and bathophenanthroline; benzimidazole derivatives such as 1,3,5-tris(N-phenylbenzimidazol-2-yl) benzene(TPBI); metal complexes such as bis(10-benzoquinolinolato)beryllium complex, 8-hydroxyquinoline Al complex, bis(2-methyl-8-quinolinato)-4-phenylphenolate aluminum; and 4,4′-bis(carbazole)biphenyl.

### Light-Emitting Element

As described above, the red light-emitting element 6R according to the present embodiment includes the anode 10R (first electrode), the red light-emitting layer 24R including a red quantum dot, the electron transport layer 26 (first contact layer) in direct contact with the red light-emitting layer 24R, and the cathode 16 (second electrode) in this order from the substrate 4 side. The red light-emitting layer 24R includes a first ligand to be coordinated to the red quantum dot, and the electron transport layer 26 includes the second ligand 34 capable of being coordinated to the red quantum dot.

The green light-emitting element 6G according to the present embodiment includes the anode 10G (first electrode), the green light-emitting layer 24G including a green quantum dot, the electron transport layer 26 (first contact layer) in direct contact with the green light-emitting layer 24G, and the cathode 16 (second electrode) in this order from the substrate 4 side. The green light-emitting layer 24G includes a first ligand to be coordinated to the green quantum dot, and the electron transport layer 26 includes the second ligand 34 capable of being coordinated to the green quantum dot.

The blue light-emitting element 6B according to the present embodiment includes the anode 10B (first electrode), the blue light-emitting layer 24B including the blue quantum dot, the electron transport layer 26 (first contact layer) in direct contact with the blue light-emitting layer 24B, and the cathode 16 (second electrode) in this order from the substrate 4 side. The blue light-emitting layer 24B includes a first ligand to be coordinated to the blue quantum dot, and the electron transport layer 26 includes the second ligand 34 capable of being coordinated to the blue quantum dot.

### Sealing Layer

The sealing layer 8 covers the light-emitting element layer 6 and seals each light-emitting element included in the display device 2. The sealing layer 8 reduces permeation of moisture, oxygen, and the like into the light-emitting element layer 6 and the like from the outside the display device 2 on the sealing layer 8 side. The sealing layer may have, for example, a layered structure of an inorganic sealing film made of an inorganic material and an organic sealing film made of an organic material. The inorganic sealing film is formed by chemical vapor deposition (CVD) and constituted by a silicon oxide film, a silicon nitride film, a silicon oxynitride film, or a layered film of these, for example. The organic sealing film is constituted by, for example, a coatable resin material including polyimide.

### Method for Manufacturing Display Device

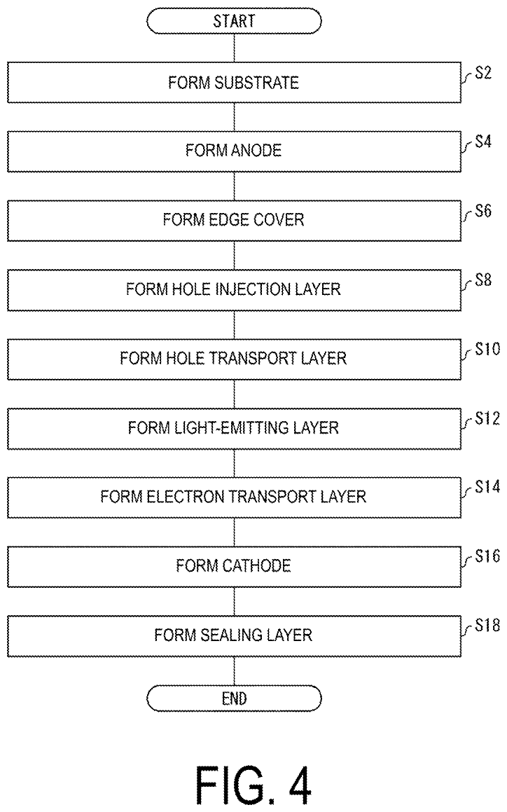

FIG. 4 is a schematic flow diagram illustrating an example of a method for manufacturing the display device 2 according to the present embodiment.

In the method for manufacturing the display device 2 according to the present embodiment, first, the substrate 4 is formed (step S2). The substrate 4 may be formed by, for example, forming, on a rigid glass substrate, a film base material and TFTs on the film base material, and then peeling the glass substrate from the film base material. The peeling of the glass substrate described above may be executed after formation of the light-emitting element layer 6 and the sealing layer 8 described below. Alternatively, the substrate 4 may be formed by, for example, forming the TFTs directly on a rigid glass substrate.

Next, the anode 10 is formed on the substrate 4 (step S4). The anode 10 may be formed by, for example, forming a thin film of a metal material by a sputtering method, a vacuum vapor deposition technique, or the like, and then patterning the thin film by dry etching or wet etching using a photoresist. Thus, the anode 10R, the anode 10G, and the anode 10B formed into island shapes on a subpixel-by-subpixel basis on the substrate 4 are obtained.

Next, the edge cover 12 is formed (step S6). In step S6, the edge cover 12 is formed by photolithography. Specifically, for example, a positive photosensitive resin serving as the material of the edge cover 12 is applied onto the upper surfaces of the substrate 4 and the anode 10. Next, a photomask having a light-transmitting portion at a position corresponding to each subpixel is placed above the applied photosensitive resin, and the photosensitive resin is irradiated with ultraviolet light or the like through the photomask. Then, the photosensitive resin irradiated with the ultraviolet light is cleaned with an appropriate developing solution. Thus, the edge cover 12 is formed between the positions corresponding to respective subpixels on the substrate 4.

Next, the hole injection layer 20 is formed (step S8). The hole injection layer 20 may be formed by any method. In step S8, for example, first, a hole transport material is dissolved or dispersed in a solvent to obtain a solution (hereinafter, referred to as a “hole injection solution”) serving as a material of the hole injection layer 20. The hole injection solution includes a hole transport material and a solvent. Then, the hole injection solution is applied and solidified on the edge cover 12 and the anode 10.

Here, in a case where the hole injection layer 20 is formed in common for a plurality of light-emitting elements, the hole injection solution may be applied onto the entire surface of the edge cover 12 and the anode 10 by a bar coating method, a spin coating method, or the like, and the hole injection solution may be solidified by heating or the like. In a case where the hole injection layer 20 is formed individually for each light-emitting element, the hole injection solution may be applied to a given position on the edge cover 12 and the anode 10 using a printing technique such as an ink-jet method, and the hole injection solution may be solidified by heating or the like. Alternatively, in a case where the hole injection layer 20 is formed individually for each light-emitting element, the hole injection solution may be applied onto an entire surface and solidified, and the solidified hole injection solution may be patterned using a photolithography technique.

Next, the hole transport layer 22 is formed (step S10). The hole transport layer 22 may be formed by any method. In step S10, for example, a hole transport material is first dissolved or dispersed in a solvent to obtain a solution (hereinafter, referred to as a “hole transport solution”) serving as a material of the hole transport layer 22. The hole transport solution includes a hole transport material and a solvent. The hole transport solution is then applied on the hole injection layer 20 (and optionally the edge cover 12, and the like) and solidified.

Next, the light-emitting layer 24 is formed (step S12). The red light-emitting layer 24R, the green light-emitting layer 24G, and the blue light-emitting layer 24B may be formed in any order. The light-emitting layer 24 may be formed by any method.

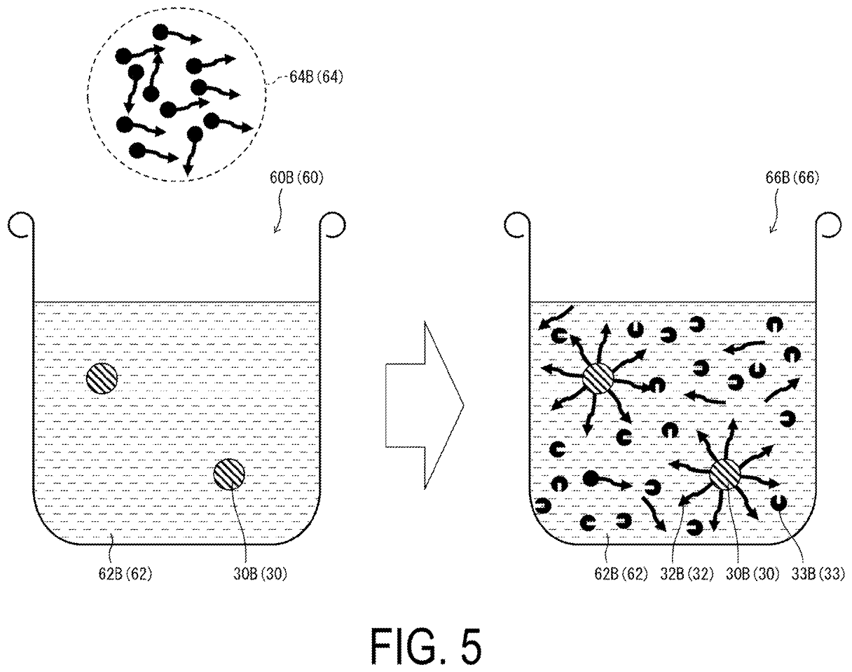

FIG. 5 is a schematic diagram illustrating an operation of preparing a solution 66B (hereinafter, referred to as a “blue light-emitting solution 66B”) serving as a material of the blue light-emitting layer 24B illustrated in FIG. 2.

As illustrated in FIG. 5, in the formation of the blue light-emitting layer 24B in step S12, for example, first, a first capping agent 64B is added to a quantum dot dispersion solution 60B containing the blue quantum dot 30B and a solvent 62B to obtain a blue light-emitting solution 66B (first liquid). The blue light-emitting solution 66B is then applied and solidified on the hole transport layer 22 (and optionally the edge cover 12, and the like). Here, the blue light-emitting solution 66B is applied onto an upper surface of the anode 10B exposed from the opening of the edge cover 12.

For example, the first ligand 32B and a byproduct 33B may be generated from the first capping agent 64B in the solvent 62B, and the first ligand 32B may be coordinated to the surface of the blue quantum dot 30B. For example, in a case where a metal halide compound (MX₂) or a metal chalcogen compound (MY) is used as the first capping agent 64B and a polar solvent is used as the solvent 62B, a halide ion (X⁻) or a chalcogenide ion (Y²⁻) and a metal ion (M²⁺) are generated from the first capping agent 64B as shown in the following chemical formula (1) or (2). As the first ligand 32B, a halide ion (X⁻) or a chalcogenide ion (Y²⁻) is coordinated to the blue quantum dot 30B. The metal ion (M²⁺) is the byproduct 33B.

### Chem. 1

MX₂⇄M²⁺+2X⁻ (1)

MY⇄M²⁺+2Y²⁻ (2)

Here, M represents a metal element, X represents a halogen element, Y represents a chalcogen element, and Y²⁻ represents a chalcogenide ion.

The halogen element is a group XVII element in the new IUPAC system. The halogen element includes fluorine (F), chlorine (Cl), bromine (Br), and iodine (I).

The chalcogen element is a group XVI element in the new IUPAC system. The chalcogen element includes oxygen (O), sulfur(S), selenium (Se), tellurium (Te), and polonium (Po).

For example, the first capping agent 64B may be directly coordinated to the surface of the blue quantum dot 30B. In this case, the first ligand 32B is the same as the first capping agent 64B and the byproduct 33B is not generated. For example, in a case where an oleic acid is used as the first capping agent 64B, the oleic acid is coordinated to the blue quantum dot 30B as the first ligand 32B.

In any case, the blue light-emitting solution 66B includes the blue quantum dot 30B and the first ligand 32B to be coordinated to the blue quantum dot 30B.

The formation of the green light-emitting layer 24G and the red light-emitting layer 24R in step S12 is similar to the formation of the blue light-emitting layer 24B in step S12, and thus the detailed description thereof will not be repeated.

In the disclosure, unless otherwise specified, the “quantum dot dispersion solution 60” refers to any one of the quantum dot dispersion solution used in the step of forming the red light-emitting layer 24R, the quantum dot dispersion solution used in the step of forming the green light-emitting layer 24G, and the quantum dot dispersion solution 60B used in the step of forming the blue light-emitting layer 24B. The “solvent 62” refers to any one of the solvent used in the step of forming the red light-emitting layer 24R, the solvent used in the step of forming the green light-emitting layer 24G, and the solvent 62B used in the step of forming the blue light-emitting layer 24B. The “first capping agent 64” refers to any one of the first capping agent used in the step of forming the red light-emitting layer 24R, the first capping agent used in the step of forming the green light-emitting layer 24G, and the first capping agent 64B used in the step of forming the blue light-emitting layer 24B. The “light-emitting solution 66” refers to any one of the red light-emitting solution used in the step of forming the red light-emitting layer 24R, the green light-emitting solution used in the step of forming the green light-emitting layer 24G, and the blue light-emitting layer 24B generated in the step of forming the blue light-emitting solution 66B.

In the disclosure, unless otherwise specified, the “byproduct 33” refers to any one of a byproduct generated in the step of forming the red light-emitting layer 24R, a byproduct generated in the step of forming the green light-emitting layer 24G, and the byproduct 33B generated in the step of forming the blue light-emitting layer 24B.

Next, the electron transport layer 26 is formed (step S14). The electron transport layer 26 may be formed by any method including an operation of applying a solution serving as a material of the electron transport layer 26.

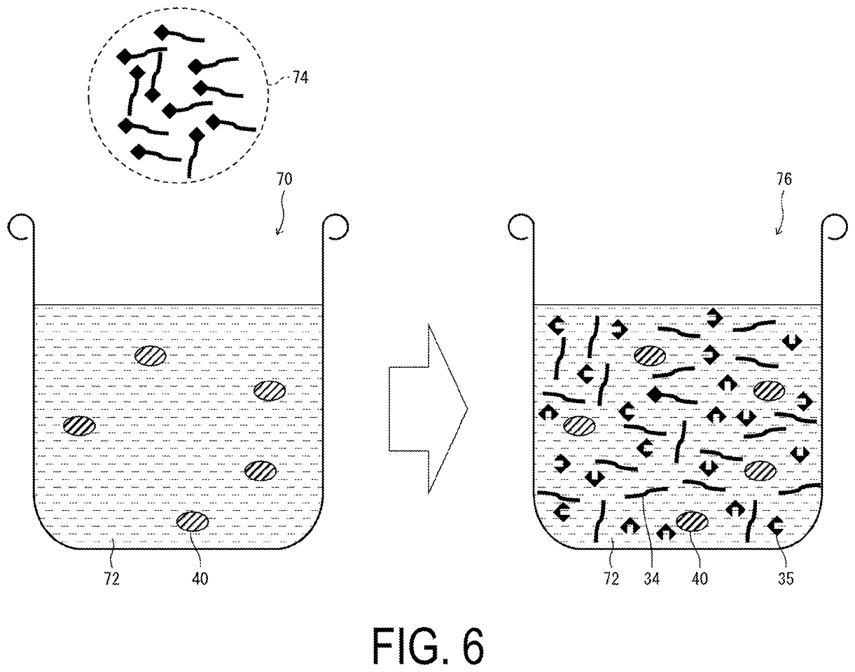

FIG. 6 is a schematic diagram illustrating an operation of preparing a solution 76 (hereinafter, referred to as an “electron transport solution 76”) serving as a material of the electron transport layer 26 illustrated in FIG. 2.

As illustrated in FIG. 6, in step S14, for example, a second capping agent 74 is added to a solution 70 containing the electron transport material 40 and a solvent 72 to obtain an electron transport solution 76 (second liquid). The electron transport solution 76 is then applied and solidified directly on the light-emitting layer 24 (and optionally the edge cover 12, and the like).

For example, in the solvent 72, the second ligand 34 and the byproduct 35 may be generated from the second capping agent 74, and the second ligand 34 may be coordinated to the surface of the blue quantum dot 30B. Further, for example, the second capping agent 74 may be directly coordinated to the surface of the blue quantum dot 30B. In this case, the second ligand 34 is the same as the second capping agent 74 and the byproduct 35 is not generated.

In a case where the electron transport material 40 is a nanoparticle, the second ligand 34 may be coordinated to the surface of the electron transport material 40.

In any case, the electron transport solution 76 includes, for the blue light-emitting element 6B, the electron transport material 40 and the second ligand 34 capable of being coordinated to the blue quantum dot 30B. The electron transport solution 76 is similar for the red light-emitting element 6R and the green light-emitting element 6G. That is, the second ligand 34 can be coordinated to any one of the red quantum dot, the green quantum dot, and the blue quantum dot 30B.

In the related art, there is a problem in that directly applying the solution onto the light-emitting layer 24 deteriorates the light-emitting layer 24, reducing the luminous efficiency and reliability of the light-emitting element. This is because the first ligand 32 contained in the light-emitting layer 24 is eluted into the applied solution. Due to decrease in an amount of the first ligand 32 in the light-emitting layer 24, the first ligand 32 is removed from the quantum dot 30, and a defect on the surface of the quantum dot 30 is easily exposed. In the quantum dot 30 in which a defect is exposed, electrons and holes are likely to undergo non-radiative recombination. In addition, the quantum dot 30 in which a defect is exposed is likely to increase in size due to Ostwald growth or aggregation. Thus, there is a problem in that the luminous efficiency and reliability of the light-emitting element are reduced.

The inventors of the disclosure have found that the above-described problem can be reduced or eliminated by selecting the first ligand 32 and the second ligand 34 in such a manner that dissolution of the first ligand 32 in the solvent and the dissolution of the second ligand 34 in the solvent compete with each other, and adding the second ligand 34 to the solution that is to be directly applied onto the light-emitting layer 24. This is because elution of the first ligand 32 into the applied solution is reduced by competition with the second ligand 34.

As described above, the electron transport solution 76 according to the present embodiment includes the second ligand 34, and the first ligand 32 competes with the second ligand 34. Thus, it is difficult for the first ligand 32 in the light-emitting layer 24 to be eluted into the electron transport solution 76. As a result, the luminous efficiency and reliability of the light-emitting element can be further improved.

In addition, in a case where the first ligand 32 moves from the light-emitting layer 24 toward the anode 10, the second ligand 34 is replenished from the electron transport layer 26 to the light-emitting layer 24. Then, the second ligand 34 protects the surface of the quantum dot 30 together with or instead of the first ligand 32. Thus, in a configuration in which the first ligand 32 moves during driving of the light-emitting element, the luminous efficiency and reliability of the light-emitting element can be improved.

Next, the cathode 16 is formed (step S16). The cathode 16 may be formed by, for example, forming a thin film of a metal material in common to a plurality of light-emitting elements by a vacuum vapor deposition method, a sputtering method, or the like. With the above, formation of the light-emitting element layer 6 is completed.

Next, the sealing layer 8 is formed (step S18). In a case in which the sealing layer 8 includes an organic sealing film, the organic sealing film may be formed by applying an organic sealing material. Further, in a case in which the sealing layer 8 includes an inorganic sealing film, the inorganic sealing film may be formed by CVD or the like. Thus, the sealing layer 8 that seals the light-emitting element layer 6 is formed.

Then, peeling of the glass substrate, bonding of the function film, and the like are performed as necessary, and the manufacturing of the display device 2 is completed. Examples of the function film include a polarizer film, a sensor film having a touch sensor panel function, a protection film, and an anti-reflection film.

### Ligand

Hereinafter, the first ligand 32 and the second ligand 34 will be described in detail.

As described above, the first ligand 32 is coordinated to the quantum dot 30. The first ligand 32 and the second ligand 34 are selected in such a manner that the dissolution of the first ligand 32 in the solvent 72 and the dissolution of the second ligand 34 in the solvent 72 compete with each other. By way of example, the first ligand 32 and the second ligand 34 may have the same functional group, may each be a halide ion, or may each be a chalcogenide ion.

Properties of an organic compound or organic ion having a functional group, for example, a coordination property with respect to a quantum dot and solubility in a solvent, depend on the functional group. Thus, when the first ligand 32 and the second ligand 34 are organic compounds or organic ions having the same functional group, the dissolution of the first ligand 32 in the solvent 72 and the dissolution of the second ligand 34 in the solvent 72 compete with each other. The functional group influencing the solubility in the solvent is selected, for example, from the group including a hydroxyl group, an aldehyde group, a carboxyl group, a carbonyl group, an ether group, an amino group, a thiol group, and a phosphine group.

An organic substance having 19 or more carbon atoms tends to be hardly dissolved in both a polar solvent and a non-polar solvent. When the first ligand 32 and the second ligand 34 are hardly soluble, it is difficult to form the light-emitting layer 24 and the electron transport layer 26. Thus, in a case where the first ligand 32 and the second ligand 34 are organic compounds or organic ions, it is preferable that the average number of carbon atoms of the first ligand 32 be 18 or less and the average number of carbon atoms of the second ligand 34 be 18 or less. Note that the average number of carbon atoms is an arithmetic mean value of the number of carbon atoms.

An organic compound or organic ion having 3 or more and 10 or less carbon atoms tends to have a strong coordinate bond with a quantum dot, and is suitable as the ligand for protecting the quantum dot. Thus, it is more preferable that the average number of carbon atoms of the first ligand 32 be 3 or more and 10 or less and the average number of carbon atoms of the second ligand 34 be 3 or more and 10 or less.

For an organic compound or organic ion, a charge transport efficiency is higher when the number of carbon atoms is smaller, but on the other hand. a hydrophobic protection ability tends to be lower. The higher the charge transport efficiency of the electron transport layer 26, the higher the luminous efficiency of the light-emitting element. The higher the protection ability of the electron transport layer 26, the longer the lifetime of the light-emitting element. Thus, it is more preferable that 30% or more and 95% or less of the first ligand 32 have 5 or less carbon atoms, and 30% or more and 95% or less of the second ligand 34 have 5 or less carbon atoms.

Note that the average number of carbon atoms of the first ligand 32 may be different from the average number of carbon atoms of the second ligand 34. Alternatively, the first ligand 32 may be the same organic compound or organic ion as the second ligand 34. When the first ligand 32 and the second ligand 34 are the same, the manufacturing cost of the light-emitting element can be reduced.

The coordination property of a halide ion with respect to a quantum dot and the solubility of the halide ion in a solvent compete with each other. Thus, when each of the first ligand 32 and the second ligand 34 is a halide ion, the dissolution of the first ligand 32 in the solvent 72 and the dissolution of the second ligand 34 in the solvent 72 compete with each other. The halide ion includes a halogen element selected from the group including fluorine (F), chlorine (Cl), bromine (Br), and iodine (I).

The first ligand 32 and the second ligand 34 are preferably selected to minimize a surface defect of the quantum dot 30. Specifically, a halide ion that minimizes a surface defect of the quantum dot 30 is preferably used as the first ligand 32 and the second ligand 34. For this reason, it is particularly advantageous for the first ligand 32 and the second ligand 34 to be the same halide ion.

On the other hand, there may be a case where the same ligand cannot be used as the first ligand 32 and the second ligand 34 from the viewpoint of solubility of the ligand in a solvent, carrier transportability of the ligand, or the like. In this case, ligands that are as similar as possible (that is, compete with each other) are preferably used as the first ligand 32 and the second ligand 34. Thus, it may also be beneficial for the first ligand 32 and the second ligand 34 to be different halide ions.

The coordination property of chalcogenide ions with respect to a quantum dot and the solubility of chalcogenide ions in a solvent compete with each other. Thus, when each of the first ligand 32 and the second ligand 34 is a chalcogenide ion, the dissolution of the first ligand 32 in the solvent 72 and the dissolution of the second ligand 34 in the solvent 72 compete with each other. The chalcogenide ion includes a chalcogen element selected from the group including oxygen (O), sulfur(S), selenium (Se), tellurium (Te), and polonium (Po).

The first ligand 32 and the second ligand 34 are preferably selected to minimize a surface defect of the quantum dot 30. Specifically, chalcogenide ions that minimize a surface defect of the quantum dot 30 may be used as the first ligand 32 and the second ligand 34. For this reason, it is particularly advantageous for the first ligand 32 and the second ligand 34 to be the same chalcogenide ion.

On the other hand, there may be a case where the same ligand cannot be used as the first ligand 32 and the second ligand 34 from the viewpoint of solubility of the ligand in a solvent, carrier transportability of the ligand, or the like. In this case, ligands that are as similar as possible (that is, compete with each other) are preferably used as the first ligand 32 and the second ligand 34. Thus, it may also be beneficial for the first ligand 32 and the second ligand 34 to be different chalcogenide ions.

In a case where a halide ion or a chalcogenide is used as the ligand, a metal halide compound or a metal chalcogen compound is usually used as the capping agent. The higher the ionization tendency of the metal element included in the capping agent, the more likely the capping agent is ionized into a metal ion and a halide ion or a chalcogenide in the material solution. Further, the higher the ionization tendency of the metal element included in the capping agent, the more easily the ionized halide ion or chalcogenide is coordinated to the quantum dot 30. Among metal elements typically used for the quantum dot 30, an element having the lowest ionization tendency is lead. Thus, it is preferable that the first capping agent 64 used in the step of forming the light-emitting layer 24 contain a first metal element having an ionization tendency equal to or higher than that of lead, and the second capping agent 74 used in the step of forming the electron transport layer 26 contain a second metal element having an ionization tendency equal to or higher than that of lead. Then, the first and second metal elements remain in the light-emitting layer 24 and the electron transport layer 26, respectively. These metal elements may be the same or different from each other.

Alkali metals and alkaline earth metals have a high ionization tendency. Thus, it is preferable that the first metal element be selected from the group including alkali metals and alkaline earth metals, and the second metal element be selected from the group including alkali metals and alkaline earth metals.

For reducing the dissolution of the quantum dot 30 in the light-emitting solution 66, the metal element included by the quantum dot 30 is preferably the same as the first metal element included by the first capping agent 64 for the light-emitting layer 24. The first metal element is selected from the group including, for example, zinc (Zn), tin (Sn), niobium (Nb), cadmium (Cd), indium (In), titanium (Ti), and zirconium (Zr). The first metal element may be different from or the same as the second metal element.

An amount of the first ligand 32 included in the light-emitting layer 24 is desirably an amount sufficient to protect the quantum dot 30, and at the same time, an amount that does not inhibit movement of holes or electrons. Specifically, a suitable range of the concentration of the first ligand 32 in the light-emitting layer 24 is 0.001 wt. % or more and 10 wt. % or less in terms of weight percentage (wt. %). For realizing this, in step S12, a suitable range of the concentration of the first ligand 32 in the light-emitting solution 66 is 0.001 mol/L or more and 0.5 mol/L or less.

An amount of the second ligand 34 included in the electron transport layer 26 is desirably an amount sufficient to reduce elution of the first ligand 32 from the light-emitting layer 24, and at the same time, an amount that does not inhibit movement of holes or electrons. That is, the amount of the second ligand 34 is preferably about the same as the amount of the first ligand 32. Specifically, a suitable range of the concentration of the second ligand 34 in the electron transport layer 26 is 0.001 wt. % or more and 10 wt. % or less in terms of weight percentage (wt. %). For realizing this, in step S14, a suitable range of the concentration of the second ligand 34 in the electron transport solution 76 is 0.001 mol/L or more and 0.5 mol/L or less.

As a method for forming the active layer 14, there is a method in which a step of applying and solidifying a solution obtained by dissolving a material in a polar solvent and a step of applying and solidifying a solution obtained by dissolving a material in a non-polar solvent are alternately repeated.

In a suitable example, a polar solvent is used as the solvent 62 contained in the light-emitting solution 66, a non-polar solvent is used as the solvent 72 contained in the electron transport solution 76, and the first ligand 32 is soluble in the non-polar solvent in a state of a simple substance (that is, free from the quantum dot 30) and is soluble in the polar solvent in a state of protecting the quantum dot 30. In the light-emitting layer 24, the first ligand 32 is in a state of protecting the quantum dot 30. Thus, the first ligand 32 is less likely to be eluted from the light-emitting layer 24. Similarly to the first ligand 32, the second ligand 34 is soluble in a non-polar solvent in a state of a simple substance and is soluble in a polar solvent in a state of protecting the quantum dot 30.

In another suitable example, a non-polar solvent is used as the solvent 62 contained in the light-emitting solution 66, a polar solvent is used as the solvent 72 contained in the electron transport solution 76, and the first ligand 32 is soluble in the polar solvent in a state of a simple substance and is soluble in the non-polar solvent in a state of protecting the quantum dot 30. In the light-emitting layer 24, the first ligand 32 is in a state of protecting the quantum dot 30. Thus, the first ligand 32 is less likely to be eluted from the light-emitting layer 24. Note that similarly to the first ligand 32, the second ligand 34 is soluble in a polar solvent in a state of a simple substance, and is soluble in a non-polar solvent in a state of protecting the quantum dot 30.

### Modified Example

A modified example of the present embodiment will be described below.

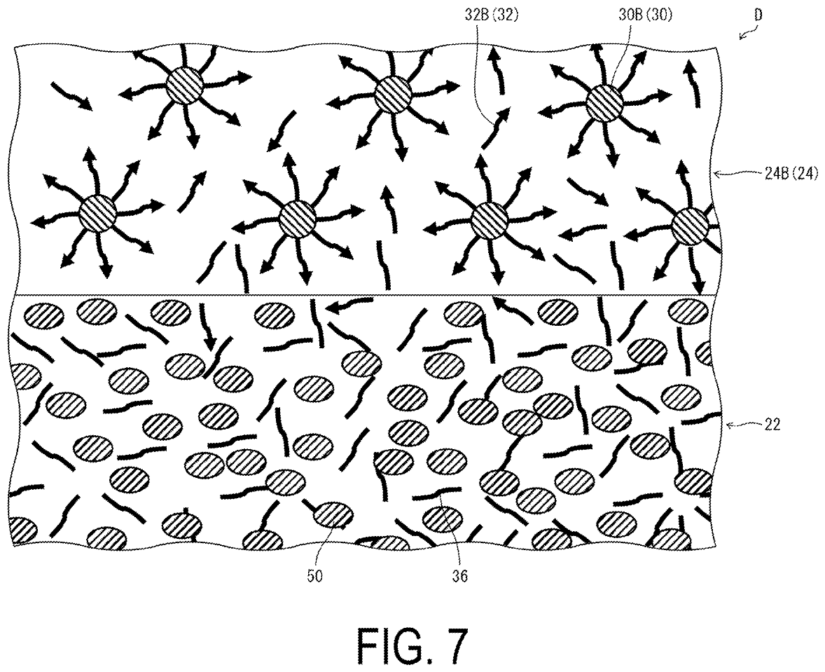

FIG. 7 is a schematic diagram illustrating a schematic configuration of the boundary between the light-emitting layer 24 and the hole transport layer 22 illustrated in FIG. 2 and the vicinity thereof. FIG. 7 corresponds to an enlarged view of a portion indicated by a box D in FIG. 2.

As illustrated in FIG. 7, the hole transport layer 22 according to the present modified example includes a hole transport material 50 having hole transport properties, and further includes a third ligand 36 capable of being coordinated to the quantum dot 30. In a case where the third ligand 36 has sufficient hole transport properties for the hole transport layer 22, the third ligand 36 may also serve as the hole transport material 50.

In step S10, for example, the hole transport material 50 and a third capping agent are added to obtain a hole transport solution. In the solvent, the third ligand 36 and a byproduct are generated from the third capping agent, and the third ligand 36 may be capable of being coordinated to the surface of the quantum dot 30. In addition, for example, the third capping agent may be directly coordinated to the surface of the quantum dot 30. In this case, the third ligand 36 is the same as the third capping agent and no byproduct is generated.

A relationship between the third ligand 36 and the first ligand 32 is preferably the same as a relationship between the second ligand 34 and the first ligand 32. That is, it is preferable that the first ligand 32 and the third ligand 36 have the same functional group, each be a halide ion, or each be a chalcogenide ion.

The third ligand 36 is preferably an organic compound or an organic ion having the same functional group as that of the first ligand 32 for the same reason as that of the second ligand 34. In addition, the average number of carbon atoms of the third ligand 36 is preferably 18 or less, and more preferably 3 or more and 10 or less. The number of carbon atoms is preferably 5 or less in 30% or more and 95% or less of the third ligand 36. The average number of carbon atoms of the third ligand 36 may be different from the average number of carbon atoms the first ligand 32, and the third ligand 36 may be the same organic compound or organic ion as the first ligand 32.

For the same reason as the second ligand 34, the third ligand 36 is preferably a halide ion in a case where the first ligand 32 is a halide ion, and is preferably a chalcogenide ion in a case where the first ligand 32 is a chalcogenide ion. In addition, the third capping agent preferably includes a third metal element having an ionization tendency equal to or higher than that of lead, and the third metal element is preferably selected from the group including alkali metals and alkaline earth metals. The first metal element may be different from or the same as the third metal element. The concentration of the third ligand 36 included in the hole transport layer 22 is desirably 0.001 wt. % or more and 10 wt. % or less.

According to the configuration of the present modified example, in a case where the first ligand 32 moves from the light-emitting layer 24 toward the cathode 16, the third ligand 36 is replenished from the hole transport layer 22 to the light-emitting layer 24. Then, the third ligand 36 protects the surface of the quantum dot 30 together with or instead of the first ligand 32. Thus, in a configuration in which the first ligand 32 moves during driving of the light-emitting element, the luminous efficiency and reliability of the light-emitting element can be improved.

### Second Embodiment

Another embodiment of the disclosure will be described below. Further, members having the same functions as those of the members described in the above-described embodiments will be denoted by the same reference numerals and signs, and the description thereof will not be repeated for the sake of convenience of description.

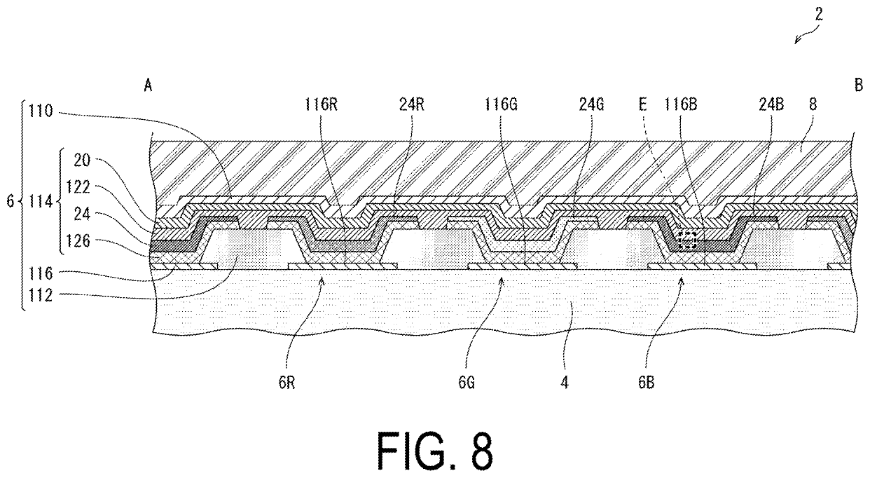

FIG. 8 is a schematic cross-sectional view of a display region DA of a display device 2 according to the present embodiment.

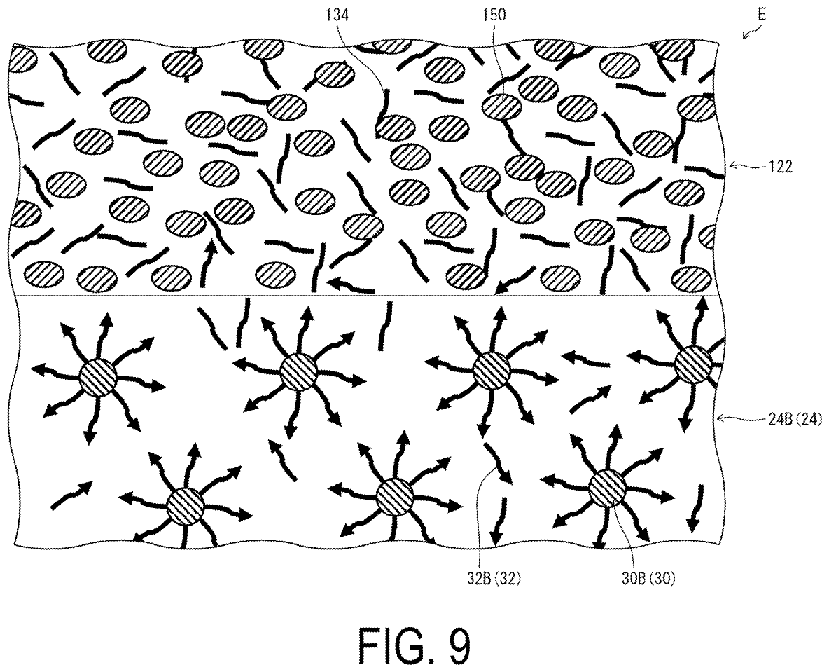

FIG. 9 is a schematic diagram illustrating a schematic configuration of a boundary between a light-emitting layer 24 and a hole transport layer 122 illustrated in FIG. 8 and the vicinity thereof. FIG. 9 corresponds to an enlarged view of a portion indicated by a box E in FIG. 8.

As illustrated in FIG. 8, a light-emitting element layer 6 according to the present embodiment includes an anode 110 (second electrode) and a cathode 116 (first electrode) facing each other, an edge cover 112 covering an edge of the cathode 116, and an active layer 114 provided between the anode 10 and the cathode 16. The active layer 14 includes a hole injection layer 20, a hole transport layer 122 (first contact layer), a light-emitting layer 24, and an electron transport layer 126 (second contact layer) in this order from the anode 110 side. The active layer 114 is also referred to as an electroluminescence layer (EL layer). This is not a limitation, and the active layer 114 may include additional components such as an electron injection layer.

The hole transport layer 122 includes a hole transport material 150 having hole transport properties, and further includes a second ligand 134 capable of being coordinated to a quantum dot 30.

The electron transport layer 126 includes an electron transport material having an electron transport property. Optionally, the electron transport layer 126 may include a third ligand capable of being coordinated to the quantum dot 30.

Thus, the light-emitting element layer 6 according to the present embodiment has the same configuration as that of the light-emitting element layer 6 according to the first embodiment or the modified example thereof described above except that the layered structure is vertically inverted. Accordingly, the present embodiment can also achieve similar advantageous effects to those of the embodiment described above.

The disclosure is not limited to each of the embodiments described above, and various modifications may be made within the scope of the claims. Embodiments obtained by appropriately combining technical approaches disclosed in each of the different embodiments also fall within the technical scope of the disclosure. Furthermore, novel technical features can be formed by combining the technical approaches disclosed in each of the embodiments.

1. A light-emitting element comprising:
a first electrode;
a light-emitting layer including a quantum dot;
a first contact layer in contact with the light-emitting layer; and
a second electrode,
wherein the light-emitting layer includes a first ligand to be coordinated to the quantum dot,
the first contact layer includes a second ligand, and
the first ligand and the second ligand have an identical functional group, each of the first ligand and the second ligand is a halide ion, or each of the first ligand and the second ligand is a chalcogenide ion,
the light-emitting layer includes a first metal element having an ionization tendency equal to or higher than an ionization tendency of lead,
the first contact layer includes a second metal element having an ionization tendency equal to or higher than the ionization tendency of lead,
the first metal element is selected from a group including alkali metals and alkaline earth metals, and
the second metal element is selected from the group including alkali metals and alkaline earth metals.

2-7. (canceled)

8. The light-emitting element according to claim 1,
wherein the first ligand and the second ligand are the halide ion, and
the first ligand and the second ligand include a halogen element selected from a group including fluorine (F), chlorine (Cl), bromine (Br), and iodine (I).

9. The light-emitting element according to claim 1,
wherein the first ligand and the second ligand are the chalcogenide ion, and
the first ligand and the second ligand include a chalcogen element selected from a group including oxygen (O), sulfur(S), selenium (Se), tellurium (Te), and polonium (Po).

10-11. (canceled)

12. The light-emitting element according to claim 1,
wherein the quantum dot includes the first metal element.

13. The light-emitting element according to claim 1,
wherein the first metal element is selected from a group including zinc (Zn), tin (Sn), niobium (Nb), cadmium (Cd), indium (In), titanium (Ti), and zirconium (Zr).

14. The light-emitting element according to claim 1,
wherein the first metal element is different from the second metal element.

15. The light-emitting element according to claim 1,
wherein the first metal element is the same as the second metal element.

16. The light-emitting element according to claim 1,
wherein the first ligand is the same as the second ligand.

17-20. (canceled)

21. The light-emitting element according to claim 1,
wherein the first contact layer is a hole transport layer or an electron transport layer.

22. The light-emitting element according to claim 1, further comprising
a second contact layer located between the light-emitting layer and the first electrode, including a third ligand, and being in contact with the light-emitting layer,
wherein the first ligand and the third ligand have an identical functional group, each of the first ligand and the third ligand is a halide ion, or each of the first ligand and the third ligand is a chalcogenide ion.

23. The light-emitting element according to claim 22,
wherein the first contact layer is one of a hole transport layer and an electron transport layer, and
the second contact layer is the other of a hole transport layer and an electron transport layer.

24. A display device comprising:
a plurality of pixels,
wherein each of the plurality of pixels includes a light-emitting element provided with a first electrode, a light-emitting layer, and a second electrode,
the first electrode is provided independently for each of the plurality of pixels,
the second electrode is provided in common for the plurality of pixels, and
the light-emitting element included in at least one pixel is the light-emitting element described in claim 1.

25. (canceled)

26. A light-emitting element comprising:
a first electrode;
a light-emitting layer including a quantum dot;
a first contact layer in contact with the light-emitting layer; and
a second electrode,
wherein the light-emitting layer includes a first ligand to be coordinated to the quantum dot,
the first contact layer includes a second ligand,
the first ligand and the second ligand have an identical functional group, each of the first ligand and the second ligand is a halide ion, or each of the first ligand and the second ligand is a chalcogenide ion, and
the first ligand is soluble in a non-polar solvent in a state of a simple substance, and is soluble in a polar solvent in a state of protecting the quantum dot.

27. The light-emitting element according to claim 26,
wherein the first ligand is an organic compound or an organic ion having the functional group, and
the second ligand is an organic compound or an organic ion having the functional group.

28. The light-emitting element according to claim 27,
wherein the functional group is selected from a group including a hydroxyl group, an aldehyde group, a carboxyl group, a carbonyl group, an ether group, an amino group, a thiol group, and a phosphine group.

29. The light-emitting element according to claim 27,
wherein an average number of carbon atoms of the first ligand is 18 or less, and an average number of carbon atoms of the second ligand is 18 or less.

30. A light-emitting element comprising:
a first electrode;
a light-emitting layer including a quantum dot;
a first contact layer in contact with the light-emitting layer; and
a second electrode,
wherein the light-emitting layer includes a first ligand to be coordinated to the quantum dot,
the first contact layer includes a second ligand,
the first ligand and the second ligand have an identical functional group, each of the first ligand and the second ligand is a halide ion, or each of the first ligand and the second ligand is a chalcogenide ion, and
the first ligand is soluble in a polar solvent in a state of a simple substance, and is soluble in a non-polar solvent in a state of protecting the quantum dot.

31. The light-emitting element according to claim 30,
wherein the first ligand is an organic compound or an organic ion having the functional group, and
the second ligand is an organic compound or an organic ion having the functional group.

32. The light-emitting element according to claim 31,
wherein the functional group is selected from a group including a hydroxyl group, an aldehyde group, a carboxyl group, a carbonyl group, an ether group, an amino group, a thiol group, and a phosphine group.

33. The light-emitting element according to claim 32,
wherein an average number of carbon atoms of the first ligand is 18 or less, and
an average number of carbon atoms of the second ligand is 18 or less.
